(19) United States
(12) Patent Application Publication
(10) Pub. No.: US 2025/0266397 A1
(43) Pub. Date: Aug. 21, 2025

(54) SEMICONDUCTOR PACKAGE INCLUDING MULTIPLE CHIP STRUCTURES

(71) Applicant: SAMSUNG ELECTRONICS CO., LTD., Suwon-si (KR)

(72) Inventors: YOUNGMIN LEE, Suwon-si (KR); KEUNG BEUM KIM, Suwon-si (KR); SANGJUN PARK, Suwon-si (KR); SEUNGDAE SEOK, Suwon-si (KR); EUNGCHANG LEE, Suwon-si (KR)

(73) Assignee: SAMSUNG ELECTRONICS CO., LTD., Suwon-si (KR)

(21) Appl. No.: 18/817,663

(22) Filed: Aug. 28, 2024

(30) Foreign Application Priority Data
Feb. 15, 2024 (KR) 10-2024-0022057

(51) Int. Cl. H01L 25/065; H01L 23/00

(52) U.S. Cl. CPC H01L 25/0657; H01L 24/08; H01L 2224/08146; H01L 2225/06541

(57) ABSTRACT

A semiconductor package may include vertically-stacked two or more chip structures, each of which includes first and second chips stacked. Each of the first and second chips may include a substrate, a via pattern penetrating through the substrate, an integrated circuit and a first pad on an active surface of the substrate, and a second pad on an inactive surface of the substrate. The first chip may further include a sub-pad between the via pattern and the second pad. In the second chip, the second pad may be directly coupled to the via pattern. The chip structures may be provided such that the active surfaces face each other, the first pads are directly bonded to each other, and the second pads are directly bonded to each other.

### CROSS-REFERENCE TO RELATED APPLICATIONS

This application claims priority to Korean Patent Application No. 10-2024-0022057, filed on Feb. 15, 2024, in the Korean Intellectual Property Office, the entire contents of which are hereby incorporated by reference.

### BACKGROUND

The present disclosure relates to a semiconductor package and a method of fabricating the same.

With the recent advance in the electronics industry, the demand for high-performance, high-speed, and compact electronic components are increasing. To meet this demand, packaging technologies of mounting a plurality of semiconductor chips in a single package are being developed.

The rapid growth in demand for portable devices in recent years has led to a need for miniaturization and light-weighting of the electronic components mounted on these devices. To address this need, it is necessary to develop semiconductor packaging technologies of reducing the size of individual components and integrating a plurality of individual components in a single package.

### SUMMARY

The disclosure provides a semiconductor package with improved structural stability and a method of fabricating the same.

The disclosure provides a semiconductor package with a reduced size.

According to an aspect of the disclosure, there is provided a semiconductor package which may include: two chip structures which are vertically stacked, wherein each of the chip structures includes a first semiconductor chip and a second semiconductor chip disposed on the first semiconductor chip, wherein the first semiconductor chip includes: a first semiconductor substrate; a first penetration via penetrating through the first semiconductor substrate; a first integrated circuit on a first active surface of the first semiconductor substrate; a first pad on the first active surface of the first semiconductor substrate; a second pad on a first inactive surface of the first semiconductor substrate; and a sub-pad between the first penetration via and the second pad, wherein the second semiconductor chip includes: a second semiconductor substrate; a second penetration via penetrating through a second semiconductor substrate; a second integrated circuit on a second active surface of the second semiconductor substrate; a third pad on the second active surface of the second semiconductor substrate; and a fourth pad on a second inactive surface of the second semiconductor substrate and directly coupled to the second penetration via, wherein the first active surface faces the second active surface, wherein the first pad is directly bonded to the third pad, wherein the fourth pad of a lower one of the chip structures is directly bonded to the second pad of an upper one of the chip structures, and wherein a distance from the first inactive surface to a bottom surface of the second pad is greater than a distance from the second inactive surface to a top surface of the fourth pad.

According to another aspect of the disclosure, there is provided a semiconductor package which may include: a base chip including: a base integrated circuit on a front surface of the base chip; an outer connection terminal on the front surface of the base chip; and a base pad (440) on a rear surface of the base chip; and chip structures vertically stacked on the base chip, wherein each of the chip structures includes a first semiconductor chip and a second semiconductor chip is provided on a front surface of the first semiconductor chip, wherein the first semiconductor chip includes: a first integrated circuit on a first active surface of a first semiconductor substrate; a first pad on the first active surface; and a pad structure on a first inactive surface of the first semiconductor substrate, wherein the second semiconductor chip includes: a second integrated circuit disposed on a second active surface of a second semiconductor substrate; a third pad on the second active surface; and a fourth pad on a second inactive surface of the second semiconductor substrate, and wherein in each of the chip structures, the first pad and the third pad are in contact with each other, the rear surface of the base chip faces the first inactive surface of a lowermost one of the chip structures, and the base pad is vertically aligned with the pad structure of the lowermost one of the chip structures.

According to still another aspect of the disclosure, there is provided a method of fabricating a semiconductor package. The method may include: providing a first wafer including a first integrated circuit on a first active surface of the first wafer, first pads on the first active surface, and sub-pads and second pads sequentially formed on a first inactive surface of the first wafer; providing a second wafer including a second integrated circuit on a second active surface of the second wafer, third pads on the second active surface, and fourth pads on a second inactive surface of the second wafer; placing the first and second wafers such that the first active surface and the second active surface face each other and the first pads and the third pads are vertically aligned; performing a thermal treatment process on the first and second wafers to bond the first wafer to the second wafer; performing a sawing process on the bonded first and second wafers to form chip structures; providing a base wafer comprising a base integrated circuit on a third active surface of the base wafer; disposing one of the chip structures on a third inactive surface of the base wafer such that the first inactive surface of the one of the chip structures faces the third inactive surface; bonding base pads of the base wafer to the second pads of the one of the chip structures to form a stack; and stacking other chip structures on a top surface of the stack to form a chip stack, wherein adjacent two of the chip structures in the chip stack are connected such that the second pads in one of the chip structures are directly bonded to the fourth pads of the other.

According to yet another aspect of the disclosure, there is provided a semiconductor package which may include: a base chip; first semiconductor chips and second semiconductor chips, which are alternately stacked on the base chip in a vertical direction; and a mold layer on the base chip, the mold layer surrounding the first and second semiconductor chips, wherein a first front surface of the first semiconductor chip and a second front surface of the second semiconductor chip face each other and are in contact with each other, wherein a first rear surface of another first semiconductor chip and a second rear surface of the second semiconductor chip face each other and are in contact with each other, wherein the first semiconductor chip includes: a first integrated circuit on a first surface of a first semiconductor substrate facing the first front surface; a first pad exposed through the first front surface; and a second pad vertically spaced apart from the first semiconductor substrate and exposed through the first rear surface, wherein the second semiconductor chip includes: a second integrated circuit on a second surface of a second semiconductor substrate facing the second front surface; a third pad exposed through the second front surface; and a fourth pad in contact with the second semiconductor substrate and exposed through the second rear surface, and wherein the first and second integrated circuits include integrated circuits of a same type, respectively.

### BRIEF DESCRIPTION OF DRAWINGS

FIGS. 1 to 6 are sectional views illustrating respective semiconductor packages, according to embodiments.

FIGS. 7 to 10 are sectional views illustrating a method of fabricating a semiconductor package, according to embodiments.

### DETAILED DESCRIPTION

The embodiments described herein are non-limiting example embodiments, and thus, the disclosure is not limited thereto and may be realized in various other forms. Each of the embodiments provided herein is not excluded from being associated with one or more features of another example or another embodiment also provided herein or not provided herein but consistent with the disclosure.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Spatially relative terms, such as “over,” “above,” “on,” “upper,” “below,” “under,” “beneath,” “lower,” “left,” “right,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features.

As used herein, an expression “at least one of” preceding a list of elements modifies the entire list of the elements and does not modify the individual elements of the list. For example, an expression, “at least one of a, b, and c” and “at least one of a, b, or c” should be understood as including only a, only b, only c, both a and b, both a and c, both b and c, or all of a, b, and c.

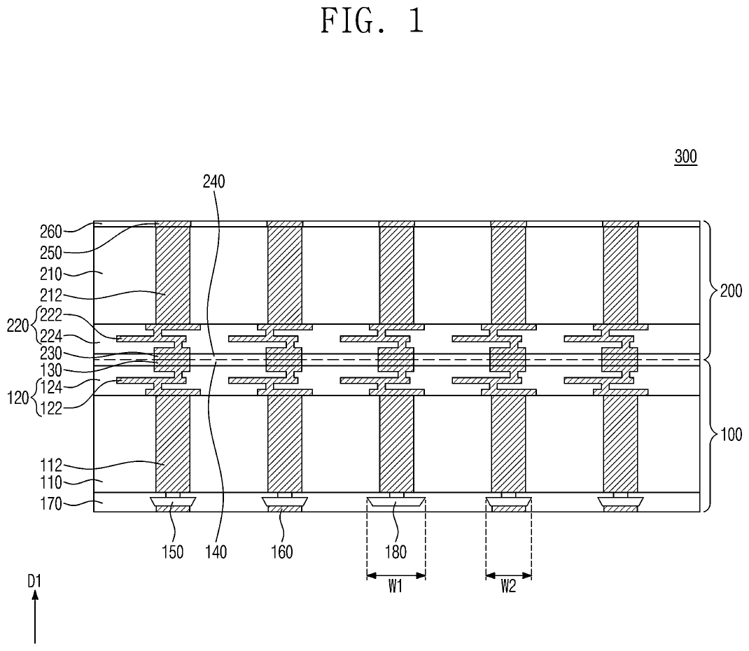

FIG. 1 is a sectional view illustrating a semiconductor package according to one or more embodiments. Referring to FIG. 1, a semiconductor package 300 may include a first semiconductor chip 100. The first semiconductor chip 100 may include a first semiconductor substrate 110 and a first interconnection layer 120 on the first semiconductor substrate 110. The first semiconductor chip 100 may have a front surface and a rear surface. In the present specification, the front surface may mean a surface of the first semiconductor chip 100, on which interconnection patterns of the first semiconductor chip 100 are formed, and the rear surface may be another surface of the first semiconductor chip 100 that is opposite to the front surface. The first semiconductor chip 100 may be provided in a face-up manner. For example, the front surface of the first semiconductor chip 100 may be a top surface of the first semiconductor chip 100.

The first semiconductor substrate 110 may include a semiconductor substrate. The first semiconductor substrate 110 may include a semiconductor material. As an example, the first semiconductor substrate 110 may be formed of or include silicon (Si), not being limited thereto. The first semiconductor substrate 110 may have an active surface and an inactive surface. In the present specification, the active surface may be defined as a surface of the semiconductor substrate, on which an integrated device or integrated circuits including active devices such as a transistor structure are formed, and the inactive surface may be defined as a surface that is opposite to the active surface. The integrated device or integrated circuits may be formed on a top surface of the first semiconductor substrate 110. The top surface of the first semiconductor substrate 110 may be an active surface. For example, the integrated device or the integrated circuits may include a memory circuit such as a memory chip (e.g., a dynamic random-access memory (DRAM), static random-access memory (SRAM), magnetoresistive random-access memory (MRAM), or FLASH memory chip), not being limited thereto. Alternatively or additionally, the integrated device or the integrated circuits may include various types of circuits including logic circuits.

The first semiconductor chip 100 may include first penetration vias 112 and the first interconnection layer 120. The first interconnection layer 120 may be provided on the active surface of the first semiconductor substrate 110. The first interconnection layer 120 may be electrically connected to the integrated device or the integrated circuits on the first semiconductor substrate 110. The first interconnection layer 120 may have a first insulating pattern 124 and a first interconnection pattern 122, which is provided in the first insulating pattern 124. The first insulating pattern 124 may be formed on or surround the integrated device or the integrated circuits, on the active surface of the first semiconductor substrate 110. The first interconnection pattern 122 may be electrically connected to the integrated device or the integrated circuits on the first semiconductor substrate 110. An upper end of the first interconnection pattern 122 may be exposed to an outside of the first insulating pattern 124 through a top surface of the first insulating pattern 124. The first interconnection pattern 122 may be formed of a conductive material (e.g., a metallic material). For example, the first interconnection pattern 122 may be formed of or include copper (Cu), not being limited thereto. The first insulating pattern 124 may be formed of or include an oxide material (e.g., silicon oxide (SiOₓ)). Herein, a lower portion of at least one of the first interconnection patterns 122 in the first insulating pattern 124 may be or include one or more of the integrated circuits on the first semiconductor substrate 110 as described above, and the other portion of the at least one of the first interconnection patterns 122 may include interconnection structures such as wirings and/or vias.

The first penetration vias 112 may penetrate through the first semiconductor substrate 110 in a first direction D1. In the present specification, the first direction D1 is perpendicular to the active surface of the first semiconductor substrate 110. An end portion of the first penetration via 112 may be coupled to the first interconnection pattern 122. An opposite end portion of the first penetration via 112 may be exposed to an outside of the first semiconductor substrate 110 through the inactive surface of the first semiconductor substrate 110.

First pads 130 may be provided on the first interconnection layer 120. Here, at least one first pad 130 may be disposed on at least one upper end of the first interconnection pattern 122 and may be connected to the first interconnection pattern 122. The first pads 130 may include a conductive material. For example, the first pads 130 may be formed of or include copper (Cu), not being limited thereto. A first insulating layer 140 may be provided on the first interconnection layer 120. The first insulating layer 140 may be formed on a top surface of the first interconnection layer 120 and may enclose the first pads 130. Top surfaces of the first pads 130 may be exposed to an outside of the first insulating layer 140 through a top surface of the first insulating layer 140. The first insulating layer 140 may be formed of or include at least one of silicon oxide (SiOₓ) or silicon nitride (SiNₓ).

Sub-pads 150 and test pads 180 may be provided below bottom surfaces of the first penetration vias 112. As shown in FIG. 1, the first penetration vias 112 may be respectively coupled to the sub-pads 150 and the test pads 180. The sub-pads 150 may be coupled to the bottom surfaces of some of the first penetration vias 112, and the test pads 180 may be coupled to the bottom surfaces of others of the first penetration vias 112. The sub-pads 150 and the test pads 180 may be connected to the first penetration vias 112 through metal vias. The metal vias may be disposed between the sub-pads 150 and the first penetration vias 112 and between the test pads 180 and the first penetration vias 112. The metal vias may be provided as distinct elements from the sub-pads 150, the test pads 180, and the first penetration vias 112 or may be formed of the same material as the sub-pads 150 and the test pads 180, forming a single structure without a connection surface or interface therebetween. The metal vias may not be provided, if necessary. In this case, the sub-pads 150 and the test pads 180 may be coupled to the bottom surfaces of the first penetration vias 112.

The sub-pads 150 and the test pads 180 may be horizontally spaced apart from each other. The number of the test pads 180 may be smaller than the number of the sub-pads 150. The test pads 180 may be placed between the sub-pads 150. However, the disclosure is not limited to this example. A first width W1 of the test pads 180 may be equal to or greater than a second width W2 of the sub-pads 150. The sub-pads 150 and the test pads 180 may be formed of or include at least one of gold, silver, copper, aluminum, nickel, tin, lead, or tungsten.

According to one or more other embodiments, one or more additional interconnection layer or interconnection patterns may be further provided below the bottom surfaces of the first penetration vias 112. These additional interconnection patterns may be disposed between the first penetration vias 112 and the sub-pads 150 and between the first penetration vias 112 and the first pads 180. Here, the sub-pads 150 and the test pads 180 may be electrically connected to the first penetration vias 112 through the metal vias and the interconnection patterns. The interconnection patterns may be formed of or include a conductive material (e.g., copper (Cu)).

Second pads 160 may be provided on bottom surfaces of the sub-pads 150. The second pads 160 may be vertically spaced apart from the first semiconductor substrate 110 and the first penetration vias 112. Each of the second pads 160 may be in contact with the bottom surface of a corresponding one of the sub-pads 150. The second pads 160 may be electrically connected to the first penetration vias 112 through the sub-pads 150. The second pads 160 may not be provided on bottom surfaces of the test pads 180. The second pads 160 may include a conductive material. For example, the second pads 160 may include copper (Cu). A second insulating layer 170 may be provided on the inactive surface of the first semiconductor substrate 110. The second insulating layer 170 may enclose the sub-pads 150, the test pads 180, and the second pads 160, on the inactive surface of the first semiconductor substrate 110. The test pads 180 may be buried in the second insulating layer 170. For example, the test pads 180 may not be exposed to an outside through a bottom surface of the second insulating layer 170. Bottom surfaces of the second pads 160 may be exposed to an outside of the first semiconductor chip 100 through the rear surface of the first semiconductor chip 100. The bottom surfaces of the second pads 160 may be exposed to an outside of the second insulating layer 170 through the bottom surface of the second insulating layer 170. The second insulating layer 170 may be formed of or include at least one of silicon oxide (SiOₓ) or silicon nitride (SiNₓ).

A second semiconductor chip 200 may be provided on the front surface of the first semiconductor chip 100. The second semiconductor chip 200 and the first semiconductor chip 100 may be disposed in a face-to-face manner. For example, the second semiconductor chip 200 may be provided on the first semiconductor chip 100 in a face-down manner. The second semiconductor chip 200 may include a second semiconductor substrate 210 and a second interconnection layer 220 on the second semiconductor substrate 210. The second semiconductor chip 200 may be disposed such that a front surface of the second semiconductor chip 200 faces the front surface of the first semiconductor chip 100. In this example, a bottom surface of the second semiconductor chip 200 may be the front surface of the second semiconductor chip 200.

The second semiconductor substrate 210 may include a semiconductor substrate 210. The second semiconductor substrate 210 may include a semiconductor material. As an example, the second semiconductor substrate 210 may be formed of or include silicon (Si), not being limited thereto. An active surface of the second semiconductor substrate 210 may face the active surface of the first semiconductor substrate 110. An integrated device or integrated circuits may be formed on the active surface of the second semiconductor substrate 210. For example, the integrated device or the integrated circuits may include a memory circuit such as a memory chip (e.g., a DRAM, SRAM, MRAM, or FLASH memory chip). Alternatively or additionally, the integrated device or the integrated circuits may include various types of circuits including logic circuits. The first and second semiconductor chips 100 and 200 may be of the same type. For example, the first and second semiconductor chips 100 and 200 may include the same type of integrated device or integrated circuits. However, the disclosure is not limited to this example, and thus, the first and second semiconductor chips 100 and 200 may include different types of integrated device or integrated circuits. For example, the first semiconductor chip 100 may include a logic circuit (e.g., a microprocessor) while the second semiconductor chip 200 includes a memory chip.

The second semiconductor chip 200 may include second penetration vias 212 and the second interconnection layer 220. The second interconnection layer 220 may be provided on the active surface of the second semiconductor substrate 210. The second interconnection layer 220 may be electrically connected to the integrated device or the integrated circuits on the second semiconductor substrate 210. The second interconnection layer 220 may include a second insulating pattern 224 and a second interconnection pattern 222 in the second insulating pattern 224. The second insulating pattern 224 may be formed on or surround the integrated device or the integrated circuits on the active surface of the second semiconductor substrate 210. The second interconnection pattern 222 may be electrically connected to the integrated device or the integrated circuits on the second semiconductor substrate 210. A bottom end of the second interconnection pattern 222 may be exposed to an outside of the second insulating pattern 224 through a bottom surface of the second insulating pattern 224. The second interconnection pattern 222 may be formed of a conductive material (e.g., a metallic material). For example, the second interconnection pattern 222 may be formed of or include copper (Cu). The second insulating pattern 224 may be formed of or include an oxide material (e.g., silicon oxide (SiOₓ)). Herein, an upper portion of at least one of the second interconnection patterns 222 in the second insulating pattern 224 may be or include one or more of the integrated circuits on the second semiconductor substrate 210 as described above, and the other portion of the at least one of the second interconnection patterns 222 may include interconnection structures such as wirings and/or vias.

The second penetration vias 212 may penetrate through the second semiconductor substrate 210 in the first direction D1. An end portion of the second penetration via 212 may be coupled to the second interconnection pattern 222. The second penetration vias 212 and the second interconnection layer 220 may be electrically connected to each other. An opposite end portion of the second penetration via 212 may be exposed to an outside through the inactive surface of the second semiconductor substrate 210.

Third pads 230 may be provided on the active surface of the second semiconductor substrate 210. Here, the third pad 230 may be disposed on the bottom end of the second interconnection pattern 222 and may be connected to the second interconnection pattern 222. The third pads 230 may include a conductive material. For example, the third pads 230 may be formed of or include copper (Cu). A third insulating layer 240 may be provided on the second interconnection layer 220. The third insulating layer 240 may be formed on the bottom surface of the second interconnection layer 220 and may enclose the third pads 230. Bottom surfaces of the third pads 230 may be exposed to an outside of the third insulating layer 240 through a bottom surface of the third insulating layer 240. The third insulating layer 240 may be formed of or include at least one of silicon oxide (SiOₓ) or silicon nitride (SiNₓ).

Fourth pads 250 may be provided on top surfaces of the second penetration vias 212. The fourth pad 250 may be a pad, which is disposed on an exposed opposite end portion of the second penetration via 212 and is connected to the second interconnection pattern 222. The fourth pads 250 may include a conductive material. For example, the fourth pads 250 may be formed of or include copper (Cu). A fourth insulating layer 260 may be provided on the inactive surface of the second semiconductor substrate 210. The fourth insulating layer 260 may be formed on the inactive surface of the second semiconductor substrate 210 and may enclose the fourth pads 250. The fourth pads 250 may be exposed to an outside of the second semiconductor chip 200 through a rear surface of the second semiconductor chip 200. In detail, top surfaces of the fourth pads 250 may be exposed to an outside of the fourth insulating layer 260 through a top surface of the fourth insulating layer 260. The fourth insulating layer 260 may be formed of or include at least one of silicon oxide (SiOₓ) or silicon nitride (SiNₓ).

The fourth pads 250 may be in contact with the second semiconductor substrate 210. The fourth pads 250 may be directly coupled to the second penetration vias 212. Since the second pads 160 of the first semiconductor chip 100 are vertically spaced apart from the first penetration vias 112 by the sub-pads 150, a distance from the inactive surface of the first semiconductor substrate 110 to the bottom surface of the second pad 160 may be greater than a distance from the inactive surface of the second semiconductor substrate 210 to the top surface of the fourth pad 250. Since the sub-pads 150 are provided on only the rear surface of the first semiconductor chip 100 and the fourth pads 250 are directly coupled to the second penetration vias 212, it may be possible to reduce a size of a semiconductor package.

The second semiconductor chip 200 may be mounted on the first semiconductor chip 100. The active surface of the first semiconductor substrate 110 may face the active surface of the second semiconductor substrate 210. The third pads 230 of the second semiconductor chip 200 may be vertically aligned with the first pads 130 of the first semiconductor chip 100. A side surface of the first semiconductor chip 100 may be aligned to a side surface of the second semiconductor chip 200 in the first direction D1. The side surface of the first semiconductor chip 100 may be coplanar with the side surface of the second semiconductor chip 200. The front surface of the first semiconductor chip 100 and the front surface of the second semiconductor chip 200 may be in contact with each other, such that the third pads 230 are connected to the first pads 130.

At an interface between the first semiconductor chip 100 and the second semiconductor chip 200, the first insulating layer 140 of the first semiconductor chip 100 may be bonded to the third insulating layer 240 of the second semiconductor chip 200. Here, the first and third insulating layers 140 and 240 may form an oxide, nitride, or oxynitride hybrid bonding structure. In the present specification, the hybrid bonding structure may refer to a bonding structure that is formed by two or more materials, which are of the same type and are fused at an interface therebetween. For example, the first and third insulating layers 140 and 240, which are bonded to each other, may form a single or continuous structure, and an interface between the first and third insulating layers 140 and 240 may not be formed or may not be visible through, for example, a scanning electron microscope (SEM). The first and third insulating layers 140 and 240 may be formed of the same material to form a single structure. For example, the first and third insulating layers 140 and 240 may be bonded to each other to form a single structure or layer. However, the disclosure is not limited to this example. The first and third insulating layers 140 and 240 may be formed of different materials from each other, and the first and third insulating layers 140 and 240 may have a connection surface or interface therebetween, thereby not forming a single or continuous structure.

The first and second semiconductor chips 100 and 200 may be in contact with each other. At an interface between the first and second semiconductor chips 100 and 200, the first pads 130 of the first semiconductor chip 100 may be directly bonded to the third pads 230 of the second semiconductor chip 200, respectively. For example, the first and third pads 130 and 230 may be provided to have an inter-metal hybrid bonding structure. The first and third pads 130 and 230, which are bonded to each other, may form a single or continuous structure, and an interface between the first and third pads 130 and 230 may not be formed or may not be visible through, for example, an SEM. In an embodiment, the first and third pads 130 and 230 may be formed of the same material to form a single structure. For example, the first and third pads 130 and 230 may be bonded to each other to form a single structure. Hereinafter, the bonding structure of the first and third pads 130 and 230 will be described in more detail, based on one first pad 130 and on third pad 230.

Referring to FIG. 1, a width of the first pad 130 may be equal to a width of the third pad 230. FIG. 1 illustrates an example, in which the first and third pads 130 and 230 have an equal width, but the disclosure is not limited to this example. The width of one of the first and third pads 130 and 230 may be greater than the width of the other. Here, at least a portion of the third pad 230 may be vertically overlapped with at least a portion of the first pad 130. The first pad 130 may have the same planar shape as the third pad 230. The first and third pads 130 and 230 may have a circular or rectangular planar shape. However, the disclosure is not limited to this example. The first and second semiconductor chips 100 and 200, which are bonded to each other, may form one first structure 300.

A mold layer may be further provided to enclose the first and second semiconductor chips 100 and 200. A top surface of the mold layer may be coplanar with the rear surface of the second semiconductor chip 200. A bottom surface of the mold layer may be coplanar with the rear surface of the first semiconductor chip 100. The mold layer may include an insulating polymer material. For example, the mold layer may include an epoxy molding compound (EMC).

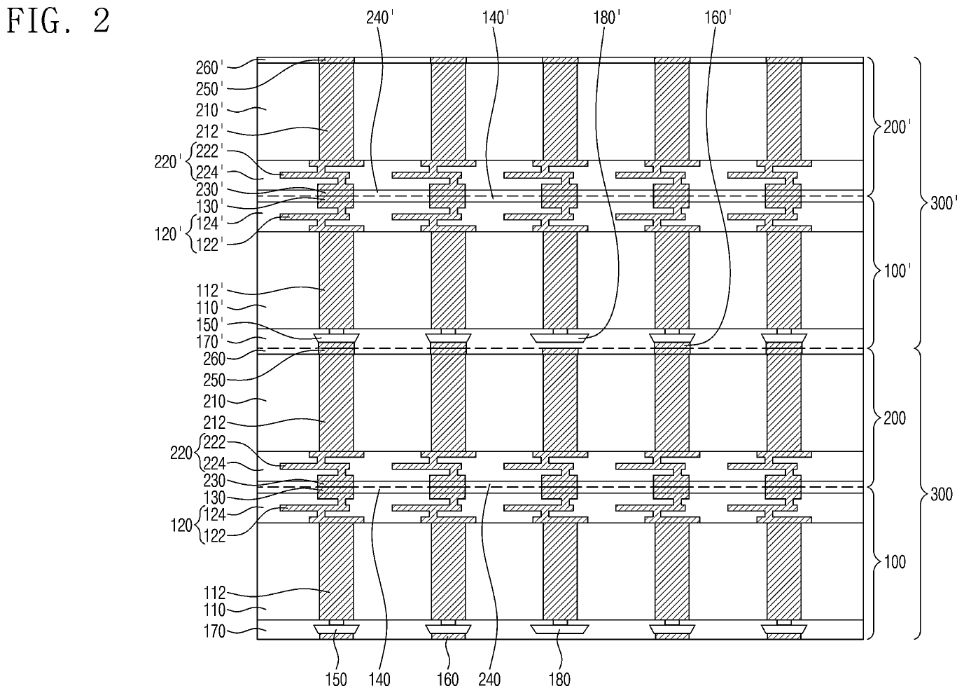

Referring to FIG. 2, two structures may be vertically stacked to form a double-layered semiconductor package. In the double-layered semiconductor package, each of the two stacked structures may have substantially the same structure as the first structure 300 described with reference to FIG. 1. For convenience in description, one of the two structures will be referred to as the first structure 300, and the other on a top surface of the first structure 300 will be referred to as a second structure 300′. Although it is referred to as the second structure 300′, the kind and material of the second structure 300′ may be substantially the same as the first structure 300. For example, the second structure 300′ may include a first semiconductor chip 100′ and a second semiconductor chip 200′, which are provided to have substantially the same features as the first semiconductor chip 100 and the second semiconductor chip 200, respectively, of the first structure 300 described with reference to FIG. 1.

The second structure 300′ may be provided on the top surface of the first structure 300. The first and second structures 300 and 300′ may be disposed on each other in a back-to-back manner. For example, a rear surface of the second semiconductor chip 200 of the first structure 300 may be in contact with a rear surface of the first semiconductor chip 100 of the second structure 300′. The inactive surface of the second semiconductor substrate 210 of the first structure 300 may face the inactive surface of the first semiconductor substrate 110′ of the second structure 300′. The fourth pads 250 of the first structure 300 may be vertically aligned with the second pads 160′ of the second structure 300′. A side surface of the first structure 300 may be spaced apart from a side surface of the second structure 300′. The first and second structures 300 and 300′ may be electrically connected to each other. It is to be understood here that the reference numbers for the structural elements included in the second structure 300′ may have a prime symbol (′) at an end thereof to distinguish from the same or corresponding structural elements included in the first structure 300.

At an interface between the first and second structures 300 and 300′, the fourth insulating layer 260 of the first structure 300 may be bonded to the second insulating layer 170′ of the second structure 300′. Here, the fourth insulating layer 260 of the first structure 300 and the second insulating layer 170′ of the second structure 300′ may form an oxide, nitride, or oxynitride hybrid bonding structure. The fourth and second insulating layers 260 and 170′, which are bonded to each other, may form a single or continuous structure, and an interface between the fourth and second insulating layers 260 and 170′ may not be formed or may not be visible through, for example, an SEM. For example, the fourth and second insulating layers 260 and 170′ may be formed of the same material to form a single structure. The fourth and second insulating layers 260 and 170′ may be bonded to form a single structure. However, the disclosure is not limited to this example. The fourth and second insulating layers 260 and 170′ may be formed of different materials and may have a connection surface or interface therebetween, thereby not forming a single or continuous structure.

At the interface between the first and second structures 300 and 300′, the fourth pads 250 of the first structure 300 may be directly bonded to the second pads 160′ of the second structure 300′. For example, the fourth pads 250 of the first structure 300 and the second pads 160′ of the second structure 300′ may form an inter-metal hybrid bonding structure. The fourth pads 250 of the first structure 300 and the second pads 160′ of the second structure 300′, which are bonded to each other, may form a single or continuous structure, and an interface between the fourth pads 250 and the second pads 160′ may not be formed or may not be visible through, for example, an SEM. For example, the fourth pads 250 and the second pads 160′ may be formed of the same material to form a single or continuous structure.

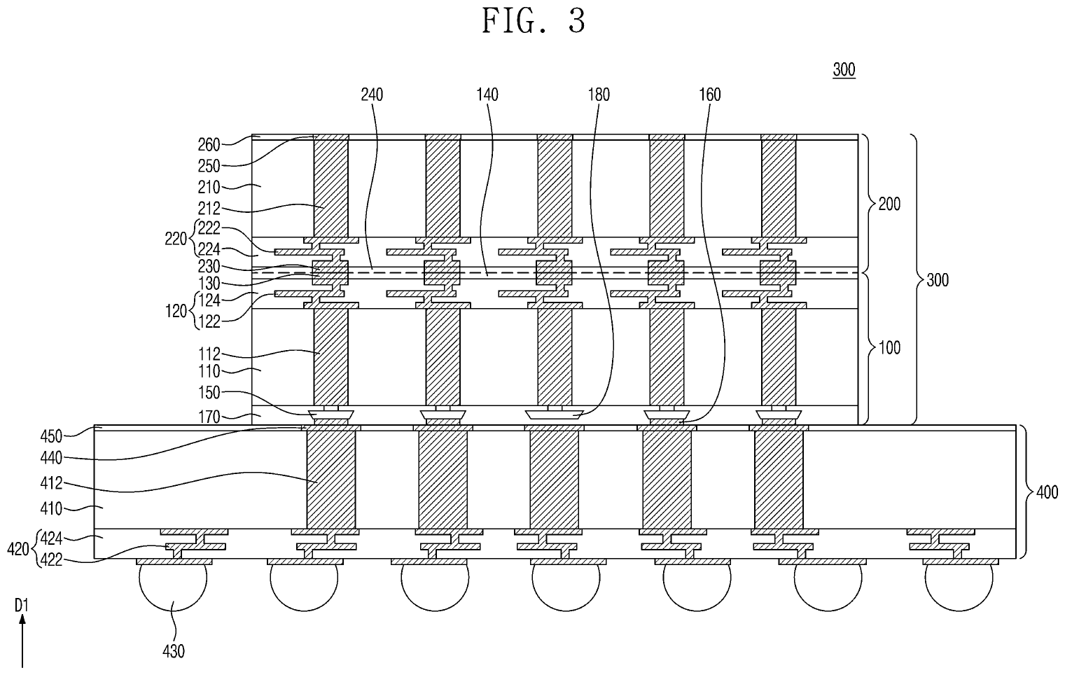

Referring to FIG. 3, a third semiconductor chip 400 may be further provided on a bottom surface of the first structure 300 described with reference to FIG. 1. The third semiconductor chip 400 may be disposed below the bottom surface of the first structure 300 in a back-to-back manner. In other words, the third semiconductor chip 400 may be provided in a face-down manner. For example, a front surface of the third semiconductor chip 400 may be a bottom surface of the third semiconductor chip 400. The third semiconductor chip 400 may include a third semiconductor substrate 410 and a third interconnection layer 420.

The third semiconductor substrate 410 may include a semiconductor substrate. The third semiconductor substrate 410 may include a semiconductor material. As an example, the third semiconductor substrate 410 may be formed of or include silicon (Si), not being limited thereto. An integrated device or integrated circuits may be formed on an active surface of the third semiconductor substrate 410. For example, the integrated device or the integrated circuits may include a logic circuit. In this case, the third semiconductor chip 400 may be a logic chip. Alternatively or additionally, the integrated device or the integrated circuits may include a memory circuit. For example, the third semiconductor chip 400 may be a memory chip (e.g., a DRAM chip, an SRAM chip, an MRAM chip, or a FLASH memory chip).

The third semiconductor chip 400 may include third penetration vias 412 and the third interconnection layer 420. The third interconnection layer 420 may be provided on the active surface of the third semiconductor substrate 410. The third interconnection layer 420 may be electrically connected to the integrated device or the integrated circuits, which are provided on the third semiconductor substrate 410. The third interconnection layer 420 may include a third insulating pattern 424 and a third interconnection pattern 422, which is provided in the third insulating pattern 424. The third insulating pattern 424 may be formed on or surround the integrated device or the integrated circuits, on the active surface of the third semiconductor substrate 410. The third interconnection pattern 422 may be electrically connected to the integrated device or the integrated circuits on the third semiconductor substrate 410. An end portion of the third penetration via 412 may be coupled to the third interconnection pattern 422. The third interconnection pattern 422 may be electrically connected to the third penetration vias 412. A portion of the third interconnection pattern 422 may protrude to a region below a bottom surface of the third insulating pattern 424. The protruding portion of the third interconnection pattern 422 may be first outer connection pads that are connected to first outer terminals 430, which will be described below. The third interconnection pattern 422 may be formed of a conductive material (e.g., a metallic material). For example, the third interconnection pattern 422 may be formed of or include copper (Cu). The third insulating pattern 424 may be formed of or include an oxide material (e.g., silicon oxide (SiOₓ)). Herein, an upper portion of at least one of the third interconnection patterns 422 in the third insulating pattern 424 may be or include one or more of the integrated circuits on the first semiconductor substrate 410 as described above, and the other portion of the at least one of the third interconnection patterns 422 may include interconnection structures such as wirings and/or vias.

The third penetration vias 412 may penetrate through the third semiconductor substrate 410 in the first direction D1. An end portion of the third penetration via 412 may be coupled to the third interconnection pattern 422. An opposite end portion of the third penetration via 412 may be exposed to an outside through the inactive surface of the third semiconductor substrate 410. The first outer terminals 430 may be provided on bottom surfaces of the first outer connection pads. The first outer terminals 430 may be electrically connected to the third semiconductor chip 400 through the first outer connection pads. The first outer terminals 430 may include solder balls or solder bumps.

Fifth pads 440 may be provided on top surfaces of the third penetration vias 412. The fifth pads 440 may be disposed on exposed opposite end portions of the third penetration vias 412 and may be connected to the third interconnection pattern 422. The fifth pads 440 may include a conductive material. For example, the fifth pads 440 may be formed of or include copper (Cu). A fifth insulating layer 450 may be provided on the inactive surface of the third semiconductor substrate 410. The fifth insulating layer 450 may be formed on the inactive surface of the third semiconductor substrate 410 and may enclose the fifth pads 440. Top surfaces of the fifth pads 440 may be exposed to an outside of the fifth insulating layer 450 through a top surface of the fifth insulating layer 450. The fifth insulating layer 450 may be formed of or include at least one of silicon oxide (SiOₓ) or silicon nitride (SiNₓ).

The first structure 300 may be mounted on the third semiconductor chip 400. A rear surface of the third semiconductor chip 400 may face a rear surface of the first semiconductor chip 100 of the first structure 300. The fifth pads 440 of the third semiconductor chip 400 may be vertically aligned with the second pads 160 of the first structure 300. The first and third semiconductor chips 100 and 400 may be in contact with each other such that the fifth and second pads 440 and 160, which are aligned with each other, are connected to each other. A width of the third semiconductor chip 400 may be equal to or larger than a width of the first structure 300.

At an interface between the first and third semiconductor chips 100 and 400, the second insulating layer 170 of the first semiconductor chip 100 may be bonded to the fifth insulating layer 450 of the third semiconductor chip 400. Here, the second and fifth insulating layers 170 and 450 may form an oxide, nitride, or oxynitride hybrid bonding structure. The second and fifth insulating layers 170 and 450, which are bonded to each other, may form a single or continuous structure, and an interface between the second and fifth insulating layers 170 and 450 may not be formed or may not be visible through, for example, an SEM. For example, the second and fifth insulating layers 170 and 450 may be formed of the same material to form a single or continuous structure. The second and fifth insulating layers 170 and 450 may be bonded to each other to form a single or continuous structure. However, the disclosure is not limited to this example. The second and fifth insulating layers 170 and 450 may be formed of different materials from each other, and the second and fifth insulating layers 170 and 450 may have a connection surface or interface therebetween, not to form a single or continuous structure.

At an interface between the first and third semiconductor chips 100 and 400, the second pads 160 of the first semiconductor chip 100 may be bonded to the fifth pads 440 of the third semiconductor chip 400. Here, the second and fifth pads 160 and 440 may be directly bonded to each other. For example, the second and fifth pads 160 and 440 may form an inter-metal hybrid bonding structure. The second and fifth pads 160 and 440, which are bonded to each other, may form a single or continuous structure, and an interface between the second and fifth pads 160 and 440 may not be formed or may not be visible through, for example, an SEM. For example, the second and fifth pads 160 and 440 may be formed of the same material to form a single or continuous structure. The second and fifth pads 160 and 440 may be bonded to each other to form a single or continuous structure. The first and third semiconductor chips 100 and 400, which are bonded to each other, may form a single stack.

FIG. 3 illustrates an example, in which the third semiconductor chip 400 is in contact with the first structure 300, but the disclosure is not limited to this example. The first structure 300 may be mounted on the third semiconductor chip 400 using connection terminals. The connection terminals may include solder balls or solder bumps. The connection terminals may be disposed between the second pads 160 and the fifth pads 440. An under-fill layer may be provided below the bottom surface of the first structure 300 to enclose the connection terminals. When the third semiconductor chip 400 is connected to the first structure 300 using the connection terminals, the third semiconductor chip 400 and the first structure 300 may be vertically spaced apart from each other.

FIG. 3 illustrates an example, in which the first structure 300 is mounted alone on the third semiconductor chip 400, but the disclosure is not limited to this example. A plurality of first structures 300 may be stacked on the third semiconductor chip 400, in which case two adjacent ones of the first structures 300 may be coupled to each other in a back-to-back manner, as described with reference to FIG. 2.

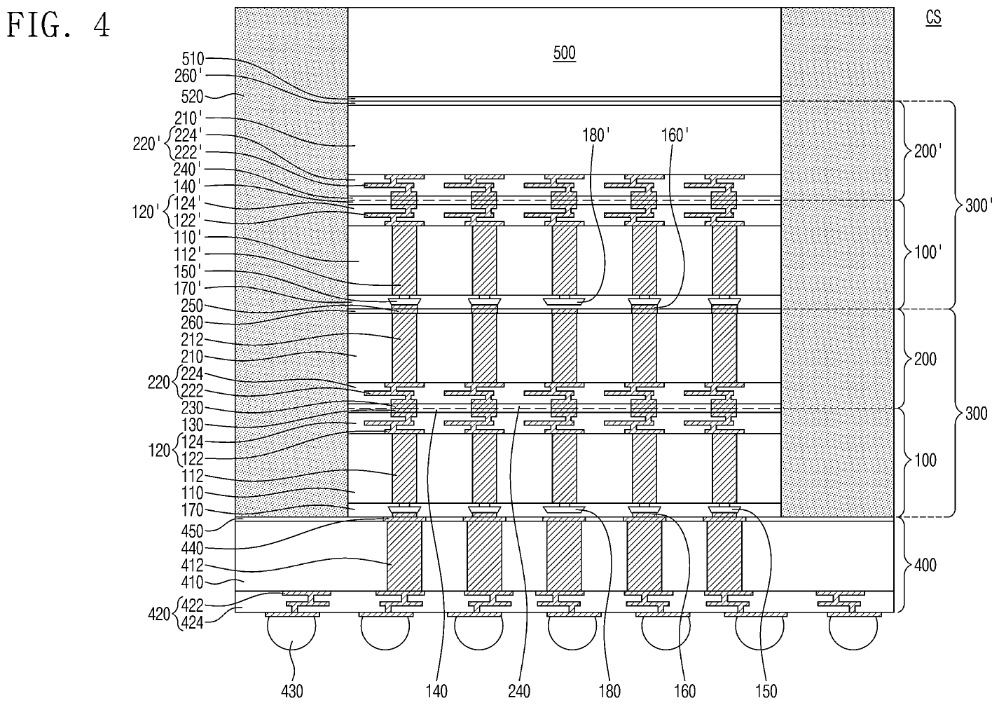

Referring to FIG. 4, a chip stack CS may be provided to have a similar structure to the stack of FIG. 3 but may further include an additional first structure 300 that is vertically stacked. The first structures 300, which are adjacent to each other, may be disposed in a back-to-back manner and may form a hybrid bonding structure, as described with reference to FIG. 2. The chip stack CS may include the third semiconductor chip 400, the first structures 300 on the third semiconductor chip 400, a fourth semiconductor chip 500 on the first structures 300, and a first mold layer 520 enclosing the first structures 300 and the fourth semiconductor chip 500. Hereinafter, the structure of the chip stack CS will be described in more detail below.

The chip stack CS may include the first structures 300, which are stacked on the third semiconductor chip 400. FIG. 4 illustrates an example, in which two first structures 300 are stacked on the third semiconductor chip 400, but the disclosure is not limited to this example; for example, the number of the first structures 300 stacked on the third semiconductor chip 400 may be changed, as desired. A width of the third semiconductor chip 400 may be greater than a width of the first structures 300. The first structures 300 may be disposed on a central portion of the third semiconductor chip 400. Hereinafter, as shown in FIG. 2, a lower one of the two first structures shown in FIG. 4 may be referred to as the first structure 300, and another one of the two first structures, which is disposed on a top surface of the first structure 300, may be referred to as the second structure 300′, for convenience in description. Although referred to by different names and different reference numbers, the first structure 300 and the second structure 300′ may have substantially the same structure, and the second structure 300′ may include the first semiconductor chip 100′ and the second semiconductor chip 200′.

Here, referring to FIG. 2, the second semiconductor chip 200′ of the second structure 300′ may not include second penetration vias 212′ and fourth pads 250′. In a case where three or more first structures 300 are stacked, the second semiconductor chip 200 of the uppermost one of the first structures 300 may not include the second penetration vias 212 and the fourth pads 250. However, in a case where two first structures 300 are stacked, the second semiconductor chip 200 of the upper one of the first structures 300 may have the same structural elements including the second penetration vias 212 and the fourth pads 250. The first and second semiconductor chips 100 and 200 of each of the first structures 300 may be bonded to each other in a face-to-face manner, and two adjacent ones of the first structures 300 may be bonded to each other in a back-to-back manner. That is, the first and second semiconductor chips 100 and 200 may be alternately stacked on the third semiconductor chip 400, and they may be provided, such that back-to-back and face-to-face structures are alternately provided.

The fourth semiconductor chip 500 may be disposed on a top surface of the second structure 300′. The fourth semiconductor chip 500 may include a semiconductor substrate. For example, the fourth semiconductor chip 500 may include a semiconductor substrate (e.g., a semiconductor wafer). The fourth semiconductor chip 500 may not include an integrated device or an integrated circuit. A sixth insulating layer 510 may be provided on a bottom surface of the fourth semiconductor chip 500. The sixth insulating layer 510 may be formed on the bottom surface of the fourth semiconductor chip 500. The sixth insulating layer 510 may be formed of or include at least one of silicon oxide (SiOₓ) or silicon nitride (SiNₓ). At an interface between the second structure 300′ and the fourth semiconductor chip 500, the sixth insulating layer 510 may be in contact with a fourth insulating layer 260′ of the second structure 300′. Here, the fourth and sixth insulating layers 260′ and 510 may form an oxide, nitride, or oxynitride hybrid bonding structure. The fourth and sixth insulating layers 260′ and 510, which are bonded to each other, may form a single or continuous structure, and an interface between the fourth and sixth insulating layers 260′ and 510 may not be formed or may not be visible through, for example, an SEM. For example, the fourth and sixth insulating layers 260′ and 510 may be formed of the same material to form a single or continuous structure. However, the disclosure is not limited to this example. The fourth and sixth insulating layers 260′ and 510 may be formed of different materials from each other and may have a connection surface or interface therebetween, thereby not forming a single or continuous structure.

In an embodiment, an adhesive layer may be provided, in place of the sixth insulating layer 510 and the fourth insulating layer 260′ of the second structure 300′. The adhesive layer may be disposed between the fourth semiconductor chip 500 and the second structure 300′. The adhesive layer may be provided on at least one of the bottom surface of the fourth semiconductor chip 500 and the rear surface of the uppermost second semiconductor chip 200′. The bottom surface of the fourth semiconductor chip 500 and the rear surface of the second semiconductor chip 200′ may be adhered to each other by the adhesive layer.

The first mold layer 520 may be disposed on the rear surface of the third semiconductor chip 400. The first mold layer 520 may be formed on the rear surface of the third semiconductor chip 400. The first mold layer 520 and may enclose the first structure 300, the second structure 300′, and the fourth semiconductor chip 500, on the rear surface of the third semiconductor chip 400. A top surface of the first mold layer 520 may be coplanar with a top surface of the fourth semiconductor chip 500. The top surface of the fourth semiconductor chip 500 may be exposed to an outside near the top surface of the first mold layer 520. The first mold layer 520 may include an insulating polymer material. For example, the first mold layer 520 may include an epoxy molding compound (EMC).

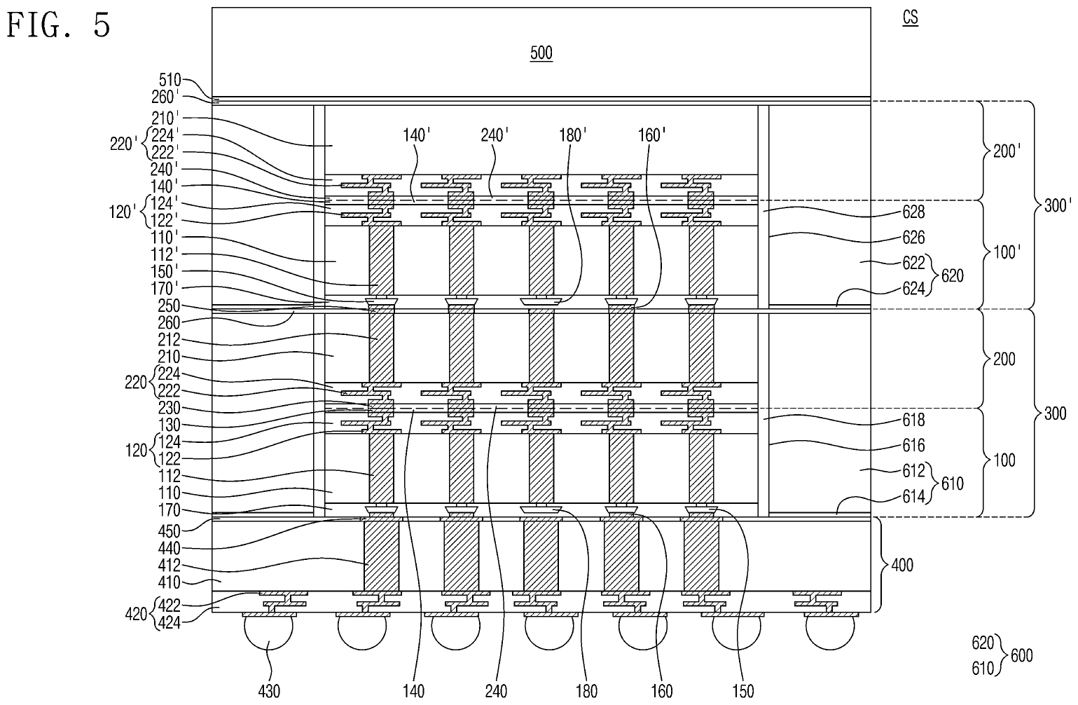

Referring to FIG. 5, the chip stack CS may have a substantially similar structure to the chip stack CS of FIG. 4 but may further include a connection chip 600, instead of the first mold layer 520 of the chip stack CS of FIG. 4. The connection chip 600 may include a first connection chip 610 and a second connection chip 620.

The first connection chip 610 may be disposed on the rear surface of the third semiconductor chip 400. The first connection chip 610 may be in contact with the rear surface of the third semiconductor chip 400. A top surface of the first connection chip 610 may be coplanar with the inactive surface of the second semiconductor substrate 210 of the first structure 300. The first connection chip 610 may include a first connection substrate 612 and a first connection layer 614, which is provided on a bottom surface of the first connection substrate 612. The first connection substrate 612 may be a semiconductor substrate (e.g., a semiconductor wafer). For example, the first connection substrate 612 may be a silicon substrate. However, the disclosure is not limited to this example, and the first connection substrate 612 may be formed of a ceramic, glass, or metallic material having a high thermal conductivity.

The first connection chip 610 may have a first opening 616, which is formed to penetrate through the same. For example, the first opening 616 may have an open hole shape connecting the top and bottom surfaces of the first connection chip 610. The first structure 300 may be disposed in the first opening 616 of the first connection chip 610. The first structure 300 may be spaced apart from an inner surface of the first opening 616. The side surface of the first structure 300 may face the inner surface of the first opening 616. A first filling layer 618 may be provided to fill a space between the first opening 616 and the first structure 300. For example, the first filling layer 618 may fill a space between the inner surface of the first opening 616 and the side surface of the first structure 300. The first filling layer 618 may be formed of or include at least one of insulating polymer, silicon oxide (SiOₓ), or silicon nitride (SiNₓ).

The fourth insulating layer 260 may be provided on the top surface of the first connection chip 610. Unlike the structure illustrated in FIG. 4, the fourth insulating layer 260 may be extended from the inactive surface of the second semiconductor substrate 210 to be formed on the top surface of the first connection chip 610. The fourth insulating layer 260 may be provided to enclose the fourth pads 250 and fill a space between the inactive surface of the second semiconductor substrate 210 and a bottom surface of the second structure 300′ and between the top surface of the first connection chip 610 and a bottom surface of the second connection chip 620.

The first connection layer 614 may be provided below the bottom surface of the first connection substrate 612. The first connection layer 614 and the fifth insulating layer 450 may be in contact with each other. The first connection layer 614 may be formed of or include at least one of silicon oxide (SiOₓ) or silicon nitride (SiNₓ). The first connection layer 614 and the fifth insulating layer 450 may form an oxide, nitride, or oxynitride hybrid bonding structure.

The second connection chip 620 may be provided on the top surface of the first connection chip 610. The second connection chip 620 may be vertically spaced apart from the first connection chip 610. At least a portion of the second connection chip 620 may be vertically overlapped with at least a portion of the first connection chip 610. A top surface of the second connection chip 620 may be coplanar with an inactive surface of the second semiconductor substrate 210′ of the second structure 300′. The second connection chip 620 may include a second connection substrate 622 and a second connection layer 624, which is provided on a bottom surface of the second connection substrate 622. The second connection substrate 622 may be a semiconductor substrate (e.g., a semiconductor wafer). For example, the second connection substrate 622 may be a silicon substrate. However, the disclosure is not limited to this example, and the second connection substrate 622 may be formed of a ceramic, glass, or metallic material having a high thermal conductivity. The first and second connection substrates 612 and 622 may be formed of the same material or different materials.

The second connection substrate 622 may have a second opening 626, which is formed to penetrate through the same. For example, the second opening 626 may have an open hole shape connecting the top and bottom surfaces of the second connection chip 620. The second structure 300′ may be disposed in the second opening 626 of the second connection chip 620. The second structure 300′ may be spaced apart from an inner surface of the second opening 626. The side surface of the second structure 300′ may face the inner surface of the second opening 626. A second filling layer 628 may be provided to fill a space between the second opening 626 and the second structure 300′. For example, the second filling layer 628 may be provided to fill a space between the inner surface of the second opening 626 and the side surface of the second structure 300′. The second filling layer 628 may be formed of or include at least one of insulating polymer, silicon oxide (SiOₓ), or silicon nitride (SiNₓ). The first and second filling layers 618 and 628 may be formed of the same material.

The fourth insulating layer 260′ of the second structure 300′ may be provided on the top surface of the second connection chip 620. Unlike the structure illustrated in FIG. 4, the fourth insulating layer 260′ may be extended from the inactive surface of the second semiconductor chip 200′ to be formed on the top surface of the second connection chip 620. The fourth insulating layer 260′ may be provided to fill a space between the inactive surface of the second semiconductor chip 200′ and the bottom surface of the fourth semiconductor chip 500 and a space between the top surface of the second connection chip 620 and a bottom surface of the sixth insulating layer 510.

The second connection layer 624 may be provided below the bottom surface of the second connection substrate 622. The second connection layer 624 may be in contact with the fourth insulating layer 260 of the first structure 300. The second connection layer 624 may be formed of or include at least one of silicon oxide (SiOₓ) or silicon nitride (SiNₓ). The second connection layer 624 and the fourth insulating layer 260 may form an oxide, nitride, or oxynitride hybrid bonding structure.

The fourth semiconductor chip 500 may be disposed on the top surfaces of the second connection chip 620 and the second structure 300′. Here, the fourth semiconductor chip 500 may be configured to have substantially the same features as the fourth semiconductor chip 500 described with reference to FIG. 4. However, unlike that shown in FIG. 4, a width of the fourth semiconductor chip 500 may be greater than a width of the second structure 300′. The width of the fourth semiconductor chip 500 may be equal to a width of the second connection chip 620. The fourth semiconductor chip 500 may be formed on the top surface of the second connection chip 620.

The sixth insulating layer 510 may be in contact with the fourth insulating layer 260′ of the second structure 300′. The sixth insulating layer 510 and the fourth insulating layer 260′ may form an oxide, nitride, or oxynitride hybrid bonding structure.

FIG. 5 illustrates the connection chip 600 including the first and second connection chips 610 and 620, but the disclosure is not limited to this example. The connection chip 600 may be provided in the form of a single substrate that is formed on the rear surface of the third semiconductor chip 400. The single substrate may be formed of or include at least one of silicon (Si), ceramic, glass, or metallic materials. Similar to the first connection chip 610, the single substrate may be attached to the rear surface of the third semiconductor chip 400 through an insulating layer, which is provided on a bottom surface thereof. A top surface of the single substrate may be coplanar with the inactive surface of the second semiconductor chip 200′ of the second structure 300′. The single substrate may have a third opening, which is formed to penetrate through the same. For example, the third opening may have an open hole shape connecting the top and bottom surfaces of the single substrate. The first and second structures 300 and 300′ may be disposed in the third opening. The first and second structures 300 and 300′ may be spaced apart from an inner surface of the third opening. The side surfaces of the first and second structures 300 and 300′ may face the inner surface of the third opening. A third filling layer may be provided to fill a space between the side surfaces of the first and second structures 300 and 300′ and the inner surface of the third opening. The third filling layer may be formed of the same material as the first and second filling layers 618 and 628.

The single substrate may have a structure where the first and second connection substrates 612 and 622 are seamlessly connected without any interface or connection surface. Here, the second connection layer 624 may not be provided between the first and second connection substrates 612 and 622. In addition, the fourth insulating layer 260 may not be extended to a region on the first connection substrate 612. For example, the fourth insulating layer 260 may be provided to fill a space between the first structure 300 and the second structure 300′, as shown in FIG. 4. The first connection substrate 612 may be extended toward the bottom surface of the fourth semiconductor chip 500 and may be connected to the second connection substrate 622. The first and second connection substrates 612 and 622, which are connected to each other, may form a single or continuous structure, in which an interface or connection surface between the first and second connection substrates 612 and 622 is absent. The first and second connection substrates 612 and 622, which are connected to each other, may be attached to the rear surface of the third semiconductor chip 400 through the first connection layer 614, which is disposed on bottom surfaces thereof. In addition, the first and second filling layers 618 and 628 may be provided to form a single filling layer as a single continuous structure. The single filling layer may be provided to fill a space between the side surfaces of the first and second structures 300 and 300′ and inner side surfaces of the connected first and second connection substrates 612 and 622.

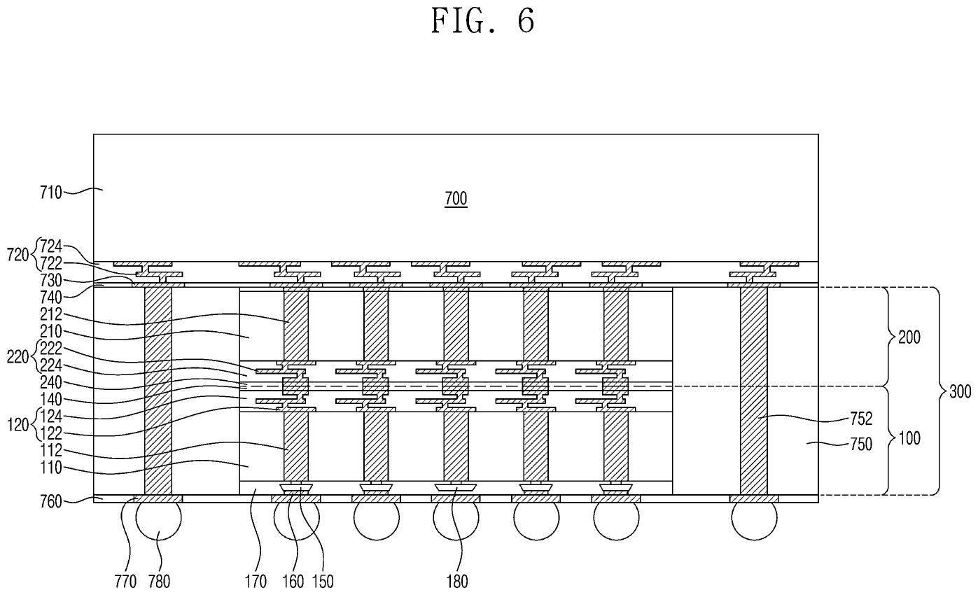

Referring to FIG. 6, a fifth semiconductor chip 700 may be further disposed on the top surface of the first structure 300, and a second mold layer 750 may be further provided to enclose the first structure 300. Here, the first structure 300 may be provided to have substantially the same features as the first structure 300 (e.g., of FIG. 1). The fifth semiconductor chip 700 may include a fifth semiconductor substrate 710 and a fifth interconnection layer 720 on the fifth semiconductor substrate 710. The fifth semiconductor chip 700 may be provided in a face-down manner. In other words, a front surface of the fifth semiconductor chip 700 may be a bottom surface of the fifth semiconductor chip 700.

The fifth semiconductor substrate 710 may include a semiconductor substrate. The fifth semiconductor substrate 710 may include a semiconductor material. As an example, the fifth semiconductor substrate 710 may be formed of or include silicon (Si), not being limited thereto. An integrated device or integrated circuits may be formed on an active surface of the fifth semiconductor substrate 710. For example, the integrated device or the integrated circuits may include a logic circuit. The fifth semiconductor chip 700 may be a logic chip.

The fifth semiconductor chip 700 may include the fifth interconnection layer 720. The fifth interconnection layer 720 may be provided on the active surface of the fifth semiconductor substrate 710. The fifth interconnection layer 720 may be electrically connected to the integrated device or the integrated circuits, which are provided on the fifth semiconductor substrate 710. The fifth interconnection layer 720 may include a fifth insulating pattern 724 and a fifth interconnection pattern 722, which is provided in the fifth insulating pattern 724. The fifth insulating pattern 724 may be formed on or surround the integrated device or the integrated circuits, which are provided on the active surface of the fifth semiconductor substrate 710. The fifth interconnection pattern 722 may be electrically connected to the integrated device or the integrated circuits, which are provided on the fifth semiconductor substrate 710. A lower end of the fifth interconnection pattern 722 may protrude to a region below a bottom surface of the fifth insulating pattern 724. The fifth interconnection pattern 722 may be formed of a conductive material (e.g., a metallic material). For example, the fifth interconnection pattern 722 may be formed of or include copper (Cu). The fifth insulating pattern 724 may be formed of or include an oxide material (e.g., silicon oxide (SiOₓ)). The protruding lower end of the fifth interconnection pattern 722 may form sixth pads 730. However, the disclosure is not limited to this example, and the sixth pad 730 may be an additional pad, which is disposed on a bottom surface of the fifth interconnection pattern 722 and is connected to the fifth interconnection pattern 722.

A seventh insulating layer 740 may be provided on the bottom surface of the fifth interconnection layer 720. The seventh insulating layer 740 may be formed on the bottom surface of the fifth interconnection layer 720 and may enclose the sixth pads 730. Bottom surfaces of the sixth pads 730 may be exposed to an outside of the seventh insulating layer 740 through a bottom surface of the seventh insulating layer 740. The seventh insulating layer 740 may be formed of or include at least one of silicon oxide (SiOₓ) or silicon nitride (SiNₓ). A width of the fifth semiconductor chip 700 may be greater than a width of the first structure 300. The top surface of the first structure 300 may be placed on a center portion of the front surface of the fifth semiconductor chip 700. When viewed in a plan view, the fifth semiconductor chip 700 may vertically overlap the entirety of the first structure 300.

The second mold layer 750 may be provided to horizontally enclose the first structure 300, and mold penetration vias 752 may be provided to vertically penetrate through the second mold layer 750. When viewed in a plan view, the second mold layer 750 may vertically overlap an outer portion of the fifth semiconductor chip 700. A top surface of the second mold layer 750 may be coplanar with the top surface of the first structure 300. A bottom surface of the second mold layer 750 may be coplanar with the bottom surface of the first structure 300. The second mold layer 750 may include an insulating polymer material. For example, the second mold layer 750 may include an epoxy molding compound (EMC). An end portion of the mold penetration via 752 may be in contact with a bottom surface of the sixth pad 730. An opposite end portion of the mold penetration via 752 may be exposed to an outside through the bottom surface of the second mold layer 750. The mold penetration vias 752 may be formed of or include copper (Cu). The mold penetration vias 752 may be electrically connected to the integrated circuit through the fifth interconnection layer 720.

Second outer connection pads 770 may be disposed on the bottom surface of the second mold layer 750 and the bottom surface of the first structure 300. The second outer connection pads 770 may be horizontally spaced apart from each other. Some of the second outer connection pads 770 may be electrically connected to the exposed opposite end portions of the mold penetration vias 752. Others of the second outer connection pads 770 may be electrically connected to the second pads 160. A protection layer 760 may be provided on the bottom surface of the second mold layer 750 and the bottom surface of the first structure 300 to enclose the second outer connection pads 770. The protection layer 760 may be formed on the bottom surface of the second mold layer 750 and the bottom surface of the first structure 300 and may enclose the second outer connection pads 770. Bottom surfaces of the second outer connection pads 770 may be exposed to an outside of the protection layer 760 through a bottom surface of the protection layer 760. Second outer terminals 780 may be provided on the second outer connection pads 770. Each of the second outer terminals 780 may be disposed on the bottom surface of a corresponding one of the second outer connection pads 770. The second outer terminals 780 may be electrically connected to the first structure 300 and the fifth semiconductor chip 700 through the second outer connection pads 770. The second outer terminals 780 may include solder balls or solder bumps.

In the semiconductor package shown in FIG. 6, the first structure 300 may be replaced by two or more first structures 300 as shown in FIG. 2, in which case an upper first structure 300 may be disposed to face the fifth semiconductor chip 700 and the protection layer 760 may be formed on a bottom surface of a lower first structure 300. Further, in this example, the second mold layer 750 may be vertically extended to enclose both the upper first structure 300 and the lower first structure.

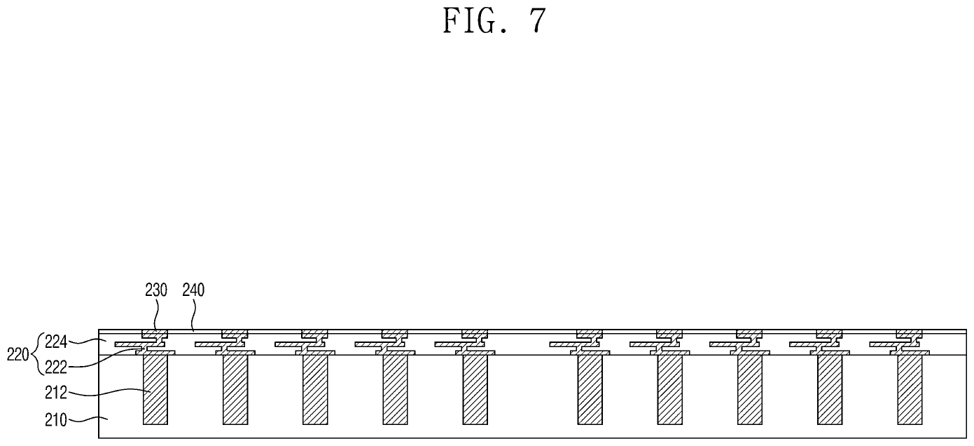

FIGS. 7 to 10 are sectional views illustrating a method of fabricating a semiconductor package, according to one or more embodiments.

Referring to FIG. 7, the second semiconductor substrate 210 may be provided. The second penetration vias 212 may be formed in the second semiconductor chip 200. The second interconnection layer 220 may be formed on the second semiconductor substrate 210. The third insulating layer 240 may be formed by depositing an insulating material on the second interconnection layer 220. The third insulating layer 240 may be patterned to form holes, which will be filled with the third pads 230. The third pads 230 may be formed on the third insulating layer 240 to fill the holes. The third pads 230 may be formed through a plating process. The top surfaces of the third pads 230 may be exposed to the outside through the top surface of the third insulating layer 240.

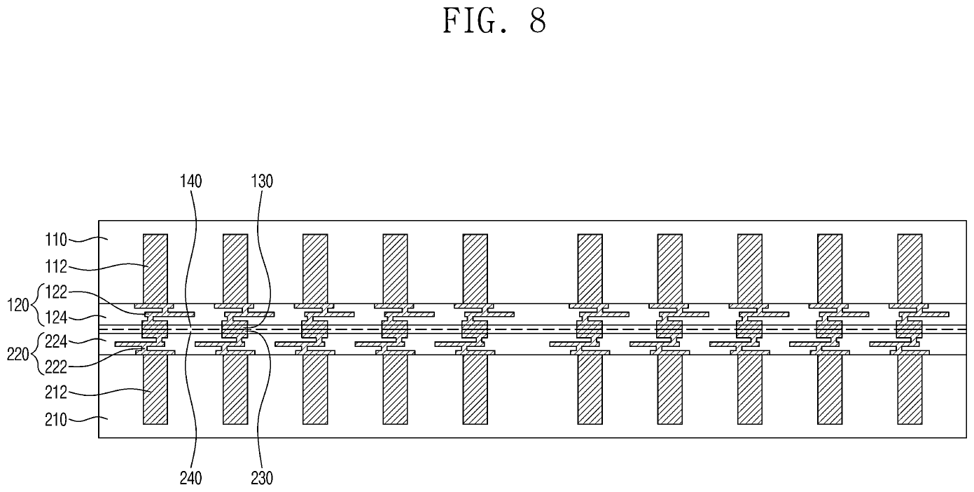

Referring to FIG. 8, the first semiconductor substrate 110 may be provided. The first penetration vias 112 may be formed in the first semiconductor chip 100. The first interconnection layer 120 may be formed on the active surface of the first semiconductor substrate 110. The first insulating layer 140 may be formed by depositing an insulating material on the first interconnection layer 120. The first insulating layer 140 may be patterned to form holes, which will be filled with the first pads 130. The first pads 130 may be formed on the first insulating layer 140 to fill the holes. The first pads 130 may be formed through a plating process. The top surface of the first pads 130 may be exposed to the outside through the top surface of the first insulating layer 140.

The first semiconductor substrate 110 may be provided on the second semiconductor substrate 210 such that the active surface thereof faces the active surface of the second semiconductor substrate 210. For example, the first semiconductor substrate 110 may be inverted such that the exposed top surface of the first pads 130 face the exposed top surface of the third pads 230. That is, the first and second interconnection layers 120 and 220 may be disposed to face each other, and this process may be performed to vertically align the first and third pads 130 and 230 with each other.

Thereafter, the first and second semiconductor substrates 110 and 210 may be in contact with each other. A thermal treatment process may be performed on the first and second semiconductor substrates 110 and 210. The thermal treatment process may include supplying heat to the first and second semiconductor substrates 110 and 210 and bonding the first and third pads 130 and 230 using the heat to form a single pad structure. In an embodiment, the bonding of the first and third pads 130 and 230 may be achieved in a natural manner. For example, the first and third pads 130 and 230 may be formed of the same material (e.g., copper (Cu)), and in this case, the first and third pads 130 and 230 may be bonded to each other by an inter-metal hybrid bonding process (e.g., Cu—Cu hybrid bonding), which is caused by a surface activation at a bonding surface between the first and third pads 130 and 230 in contact with each other. The first and third insulating layers 140 and 240 may be bonded to each other by the thermal treatment process. For example, the first and third insulating layers 140 and 240 may be bonded to each other to form a single or continuous structure.

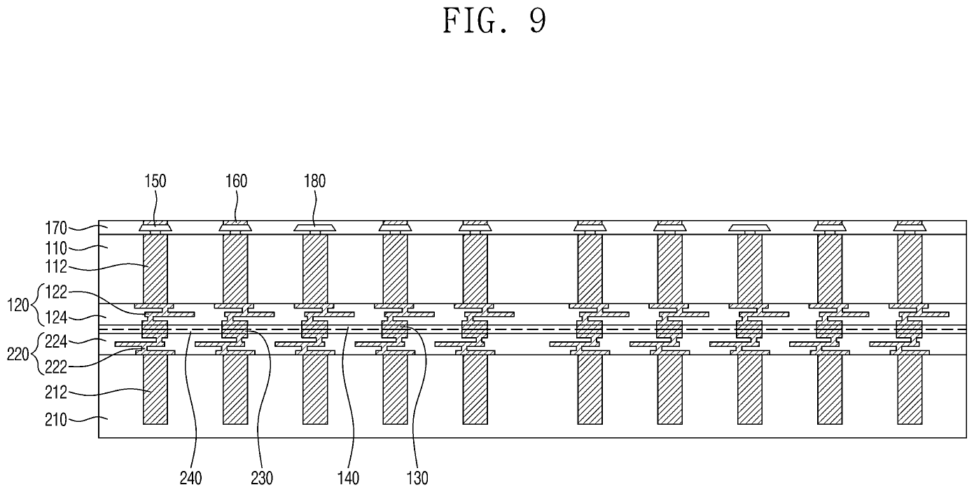

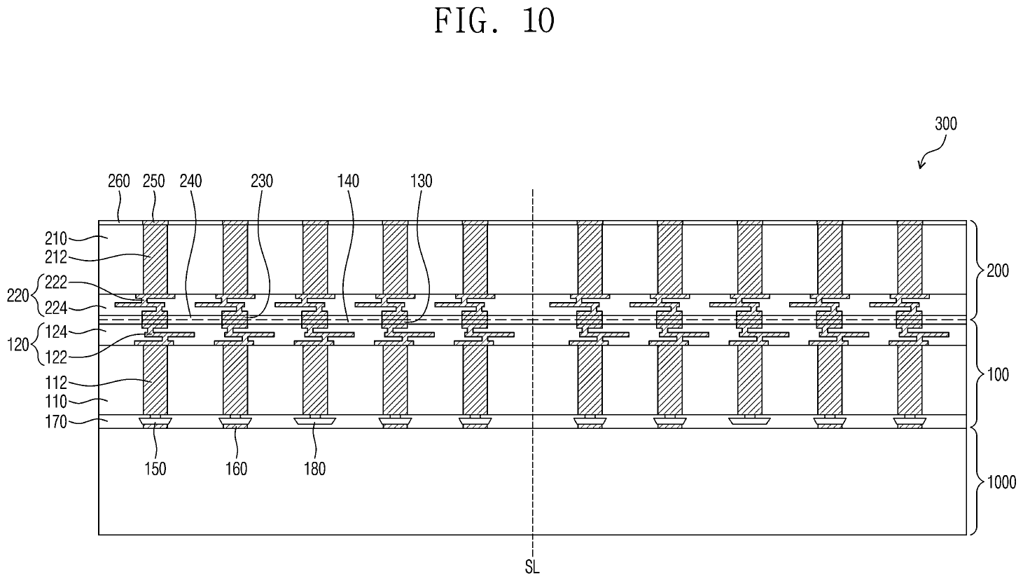

Referring to FIG. 9, the sub-pads 150, the second pads 160, and the test pads 180 may be formed on the inactive surface of the first semiconductor substrate 110. A grinding process may be performed on the inactive surface of the first semiconductor substrate 110. The grinding process may be performed to expose top surfaces of the first penetration vias 112, which are disposed in the first semiconductor substrate 110. The sub-pads 150 and the test pads 180 may be formed on the grinded inactive surface of the first semiconductor substrate 110. A first insulating material may be deposited on the grinded top surface of the first semiconductor substrate 110. The deposited first insulating material may be patterned to form holes, which will be filled with the sub-pads 150 and the test pads 180. The sub-pads 150 and the test pads 180 may be formed on the deposited first insulating material to fill the holes. In an embodiment, the sub-pads 150 and the test pads 180 may be formed simultaneously through the same process. A second insulating material may be deposited on the first insulating material. The deposited second insulating material may be patterned to form holes. The second pads 160 may be formed on the deposited second insulating material to fill the holes. The deposited first insulating material and the deposited second insulating material may constitute the second insulating layer 170. FIG. 10 illustrates an example, in which the second insulating layer 170 is formed of the first and second insulating materials, but the types and the number of insulating materials constituting the second insulating layer 170 may vary as needed. The test pads 180 may be pads, which are used to evaluate the electrical characteristics of the first and second semiconductor substrates 110 and 210. The evaluation of the electrical characteristics may include a test step of applying voltages to the test pads 180. For example, the test step may include an electrical die sorting (EDS) test. The evaluation of the electrical characteristics may be executed between the process of forming the test pads 180 and the process of forming the second pads 160.

Referring to FIG. 10, a carrier substrate 1000 may be provided. The structure of FIG. 9 may be disposed on a top surface of the carrier substrate 1000 such that it has an inverted structure. Thus, the second semiconductor chip 200 may be placed on the first semiconductor chip 100. The sub-pads 150 may be disposed to face the top surface of the carrier substrate 1000.

The fourth pads 250 and the fourth insulating layer 260 may be formed on the inactive surface of the second semiconductor substrate 210. First, a grinding process may be performed on the inactive surface of the second semiconductor substrate 210. As a result of the grinding process, top surfaces of the second penetration vias 212, which are disposed in the second semiconductor substrate 210, may be exposed to the outside of the second semiconductor substrate 210. The grinded inactive surface of the second semiconductor substrate 210 may be coplanar with the top surface of the second penetration vias 212. The fourth insulating layer 260 may be formed by depositing an insulating material on the grinded inactive surface of the second semiconductor substrate 210. The fourth insulating layer 260 may be patterned to form holes, which will be filled with the fourth pads 250. The fourth pads 250 may be formed on the fourth insulating layer 260 to fill the holes. The top surface of the fourth pads 250 may be exposed to the outside of the fourth insulating layer 260 through the top surface of the fourth insulating layer 260.

Thereafter, the carrier substrate 1000 may be removed. A sawing process may be performed along a sawing line SL to form a plurality of first structures that are separated from each other. Referring back to FIG. 1, each of the first structures separated from each other by the sawing process may correspond to the chip structure 300 (e.g., of FIG. 1).

In a semiconductor package according to the above embodiments, semiconductor chips may be directly bonded to each other, and a metal pad may be provided below only one of the two bonded semiconductor chips. Thus, it may be possible to reduce the size of the semiconductor package.

In a semiconductor package according to the above embodiments, semiconductor chips may be stacked such that active surfaces of them face each other, and in this case, it may be possible to compensate a warpage-induced pressure and thereby to improve the structural stability of the semiconductor package.

While example embodiments of the disclosure have been particularly shown and described, it will be understood by one of ordinary skill in the art that variations in form and detail may be made therein without departing from the spirit and scope of the attached claims.

1. A semiconductor package comprising two chip structures which are vertically stacked,
wherein each of the chip structures comprises a first semiconductor chip and a second semiconductor chip disposed on the first semiconductor chip,
wherein the first semiconductor chip comprises:
a first semiconductor substrate;
a first penetration via penetrating through the first semiconductor substrate;
a first integrated circuit on a first active surface of the first semiconductor substrate;
a first pad on the first active surface of the first semiconductor substrate;
a second pad on a first inactive surface of the first semiconductor substrate; and
a sub-pad between the first penetration via and the second pad,
wherein the second semiconductor chip comprises:
a second semiconductor substrate;
a second penetration via penetrating through a second semiconductor substrate;
a second integrated circuit on a second active surface of the second semiconductor substrate;
a third pad on the second active surface of the second semiconductor substrate; and
a fourth pad on a second inactive surface of the second semiconductor substrate and directly coupled to the second penetration via,
wherein the first active surface faces the second active surface,
wherein the first pad is directly bonded to the third pad,
wherein the fourth pad of a lower one of the chip structures is directly bonded to the second pad of an upper one of the chip structures, and
wherein a distance from the first inactive surface to a bottom surface of the second pad is greater than a distance from the second inactive surface to a top surface of the fourth pad.

2. The semiconductor package of claim 1, further comprising a third semiconductor chip disposed on a bottom surface of the lower one of the chip structures,
wherein the third semiconductor chip comprises a third integrated circuit on a third active surface of a third semiconductor substrate and a fifth pad on a third inactive surface of the third semiconductor substrate,
wherein a width of the third semiconductor chip is greater than a width of the chip structures,
wherein the first inactive surface of the lower one of the chip structures faces the third inactive surface, and
wherein the second pad of the lower one of the chip structures is directly bonded to the fifth pad.

3. The semiconductor package of claim 1, further comprising:
a first insulating layer on the first active surface, the first insulating surrounding the first pad; and
a second insulating layer on the second active surface, the second insulating layer surrounding the third pad,
wherein the first and second insulating layers are in contact with each other.

4. The semiconductor package of claim 1, wherein the fourth pad is directly coupled to the second penetration via,
wherein the second pad is vertically spaced apart from the first penetration via, and
wherein the second pad is electrically connected to the first penetration via through the sub-pad.

5. The semiconductor package of claim 1, further comprising a test pad, which is horizontally spaced apart from the sub-pad,
wherein a width of the test pad is greater than a width of the sub-pad.

6. (canceled)

7. The semiconductor package of claim 1, wherein a side surface of the first semiconductor chip and a side surface of the second semiconductor chip are aligned with each other in a direction perpendicular to the first active surface.

8. The semiconductor package of claim 1, further comprising:
a mold layer enclosing the chip structures;
a mold penetration via vertically penetrating the mold layer;
an outer connection terminal disposed on a bottom surface of the mold layer; and
a third semiconductor chip on the second inactive surface of the upper one of the chip structures,
wherein the third semiconductor chip comprises a third integrated circuit on a third active surface of a third semiconductor substrate and a fifth pad on the third active surface,
wherein a width of the fourth semiconductor chip is greater than a width each of the chip structures,
wherein the second inactive surface of the upper one of the chip structures faces the third active surface,
wherein the fourth pad of the upper one of the chip structures is directly bonded to the fifth pad, and
wherein the mold penetration via is extended from the third active surface and is connected to the outer connection terminal.

9. The semiconductor package of claim 1, further comprising a third semiconductor chip disposed on a top surface of the chip structures and an insulating layer interposed between a top surface of the upper one of the chip structures and the third semiconductor chip,
wherein the third semiconductor chip is attached to the top surface of the upper one of the chip structures through the insulating layer.

10. A semiconductor package comprising:
a base chip comprising:
a base integrated circuit on a front surface of the base chip;
an outer connection terminal on the front surface of the base chip; and
a base pad on a rear surface of the base chip; and
chip structures vertically stacked on the base chip,
wherein each of the chip structures comprises a first semiconductor chip and a second semiconductor chip is provided on a front surface of the first semiconductor chip,
wherein the first semiconductor chip comprises:
a first integrated circuit on a first active surface of a first semiconductor substrate;
a first pad on the first active surface; and
a pad structure on a first inactive surface of the first semiconductor substrate,
wherein the second semiconductor chip comprises:
a second integrated circuit disposed on a second active surface of a second semiconductor substrate;
a third pad on the second active surface; and
a fourth pad on a second inactive surface of the second semiconductor substrate, and
wherein in each of the chip structures, the first pad and the third pad are in contact with each other, the rear surface of the base chip faces the first inactive surface of a lowermost one of the chip structures, and the base pad is vertically aligned with the pad structure of the lowermost one of the chip structures.

11. The semiconductor package of claim 10, further comprising:
a base insulating layer on the rear surface of the base chip, the base insulating layer surrounding the base pad; and
an insulating layer on the first inactive surface of the lowermost one of the chip structures, the insulating layer surrounding the pad structure,
wherein the base insulating layer and the insulating layer are in contact with each other.

12. The semiconductor package of claim 10, wherein the first semiconductor chip further comprises a first penetration via, which penetrates through the first semiconductor substrate and is electrically connected to the first integrated circuit,
wherein the pad structure comprises a sub-pad and a second pad,
wherein the sub-pad is disposed between the first penetration via and the second pad, and
wherein the second pad is electrically connected to the first integrated circuit through the sub-pad and the first penetration via.

13. The semiconductor package of claim 12, further comprising a test pad on the first inactive surface, the test pad being horizontally spaced apart from the sub-pad,
wherein the test pad and the sub-pad are comprises a same material.

14. The semiconductor package of claim 12, wherein a distance from the first inactive surface to a bottom surface of the second pad is greater than a distance from the second inactive surface to a top surface of the fourth pad.

15. The semiconductor package of claim 10, further comprising:
a third semiconductor chip on a top surface of the uppermost one of the chip structures; and
an insulating layer between the top surface of the uppermost one of the chip structures and the third semiconductor chip,
wherein the third semiconductor chip is attached to the top surface of the uppermost one of the chip structures through the insulating layer.

16. The semiconductor package of claim 15, further comprising a connection substrate on the rear surface of the base chip, the connection substrate comprising an opening,
wherein the chip structures are disposed in the opening,
wherein a top surface of the connection substrate is coplanar with the top surface of the uppermost one of the chip structures,
wherein the third semiconductor chip is on the top surface of the connection substrate and the top surface of the uppermost one of the chip structures, and
wherein the insulating layer is extended from a region between the third semiconductor chip and the uppermost one of the chip structures to a region on the top surface of the connection substrate to fill a space between the connection substrate and the third semiconductor chip.

17. The semiconductor package of claim 16, wherein an inner side surface of the opening is spaced apart from side surfaces of the chip structures, and
wherein a filling layer filling a space between the inner side surface of the opening and the side surface of the chip structures.

18-23. (canceled)

24. A semiconductor package comprising:
a first chip structure comprising a first semiconductor chip and a second semiconductor chip connected to and stacked on the first semiconductor chip; and
a second chip structure comprising a third semiconductor chip and a fourth semiconductor chip connected to and stacked on the third semiconductor chip,
wherein the second chip structure is stacked on the first chip structure such that the third semiconductor chip is connected to and stacked on the second semiconductor chip,
wherein an active surface of the first semiconductor chip with a first active device thereon faces an active surface of the second semiconductor chip with a second active device thereon, and
wherein an inactive surface of the second semiconductor chip opposite to the active surface thereof faces an inactive surface of the third semiconductor chip opposite to an active surface thereof with a third active device thereon.

25. The semiconductor package of claim 24, wherein the active surface of the third semiconductor chip faces an active surface of the fourth semiconductor chip with a fourth active device thereon.

26. The semiconductor package of claim 24, further comprising:
a base chip on which the first chip structure is stacked, the base chip connected to the first chip structure; and
a molding layer or a connection substrate surrounding the first and second chip structures, on the base chip,
wherein an inactive surface of the first semiconductor chip faces the base chip.

27. The semiconductor package of claim 26, further comprising a test pad on an inactive surface of the first semiconductor chip, the test pad not connected to the base chip.
